(19) United States
(12) Patent Application Publication
(10) Pub. No.: US 2025/0386693 A1
(43) Pub. Date: Dec. 18, 2025

(54) ARRAY SUBSTRATE AND DISPLAY PANEL

(71) Applicant: Sharp Display Technology Corporation, Kameyama City (JP)

(72) Inventors: Tetsuo KIKUCHI, Kameyama City (JP); Hajime IMAI, Kameyama City (JP); Hitoshi TAKAHATA, Kameyama City (JP); Setsuji NISHIMIYA, Kameyama City (JP); Teruyuki UEDA, Kameyama City (JP); Yusuke INOUE, Kameyama City (JP)

(21) Appl. No.: 19/214,200

(22) Filed: May 21, 2025

(30) Foreign Application Priority Data
Jun. 17, 2024 (JP) 2024-097338

(51) Int. Cl. H10K 59/131; H10K 59/121

(52) U.S. Cl. CPC H10K 59/131; H10K 59/1216

(57) ABSTRACT

An array substrate includes a first TFT including: a first insulating film disposed on an upper side of an insulating substrate; a first semiconductor film made of LTPS; a second insulating film; a first gate electrode composed of a first conducting film overlapping the first semiconductor film; a third insulating film; a first source relay electrode and a first drain relay electrode each composed of a second conducting film free of copper and connected to the first semiconductor film through first contact holes; a fourth insulating film; and a first source electrode and a first drain electrode each composed of a third conducting film containing copper and respectively connected to the first source relay electrode and the first drain relay electrode through second contact holes.

### BACKGROUND

### 1. Field

This technology relates to array substrates and display panels.

### 2. Description of the Related Art

Thin-film transistors (TFTs) are known to be used as switching elements in display panels, such as liquid crystal panels and organic electroluminescence (EL) panels. TFTs are formed by stacking various types of thin films on an array substrate (active matrix substrate, TFT substrate) in a display panel. Japanese Patent No. 6916256 discloses that two types of TFTs are formed on the same substrate. Specifically, the TFTs in Japanese Patent No. 6916256include a first TFT having an active layer (semiconductor film) made of a low-temperature polycrystalline silicon (LTPS) with electrical conductivity as a source and a drain, and a second TFT having an active layer made of an oxide semiconductor with electrical conductivity as a source and a drain.

An array substrate where low-temperature polysilicon (LTPS) is used as an active layer of a TFT and a copper (Cu)-containing conductor is used for wires has the problem that copper in the wires easily penetrates the active layer made of LTPS to reduce the mobility and reliability of the TFT. In recent years, however, there has been a growing demand to achieve high-frequency driving and low power consumption by using low-resistance copper wires in array substrates of medium-and large-size displays or other displays.

The technology disclosed herein has been completed based on the above circumstances, and it is desirable to provide an array substrate and a display panel in which copper in wires is unlikely to penetrate a semiconductor film made of LTPS even when a copper (Cu)-containing conductor is used for the wires.

### SUMMARY

According to a first aspect of the disclosure, there is provided an array substrate including a first TFT including: a first insulating film disposed on an upper side of an insulating substrate; a first semiconductor film disposed on the first insulating film and made of a low-temperature polysilicon semiconductor material; a second insulating film disposed on the first semiconductor film; a first electrode disposed on the second insulating film and composed of a first conducting film overlapping the first semiconductor film; a third insulating film disposed on the first electrode; a first relay electrode composed of a second conducting film free of copper and disposed on the third insulating film, the first relay electrode being connected to the first semiconductor film through a first contact hole penetrating at least the third insulating film; a fourth insulating film disposed on the first relay electrode; and a second electrode composed of a third conducting film containing copper and disposed on the fourth insulating film, the second electrode being connected to the first relay electrode through a second contact hole penetrating the fourth insulating film.

According to a second aspect of the disclosure, there is provided a display panel including the array substrate according to the first aspect.

### BRIEF DESCRIPTION OF THE DRAWINGS

FIG. 1 is a cross-sectional view of a first TFT, a second TFT, and their surrounding area in an array substrate according to a first embodiment;

FIG. 2 is an enlarged cross-sectional view of a first contact hole, a second contact hole, and their surrounding area in the array substrate of the first embodiment;

FIG. 3 is a cross-sectional view of a first TFT, a second TFT, and their surrounding area in an array substrate of a second embodiment;

FIG. 4 is an enlarged cross-sectional view of a first contact hole, a second contact hole, and their surrounding area in the array substrate of the second embodiment;

FIG. 5 is a cross-sectional view of a first TFT, a third TFT, and their surrounding area in an array substrate of a third embodiment;

FIG. 6 is a cross-sectional view of a first TFT, a second TFT, and their surrounding area in an array substrate of a fourth embodiment; and

FIG. 7 is a cross-sectional view of a first TFT, a third TFT, and their surrounding area in an array substrate of another embodiment.

### DESCRIPTION OF THE EMBODIMENTS

### First Embodiment

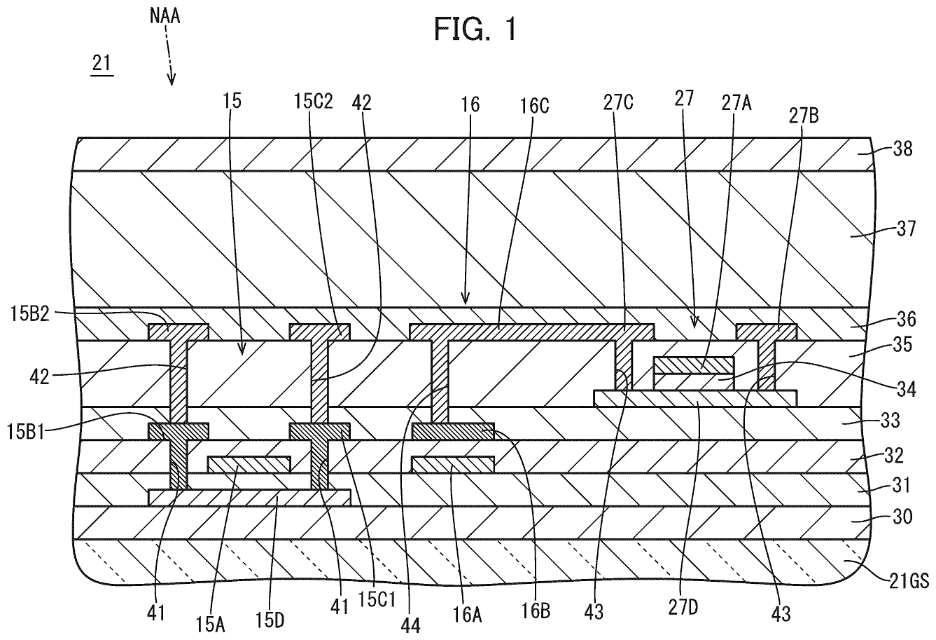

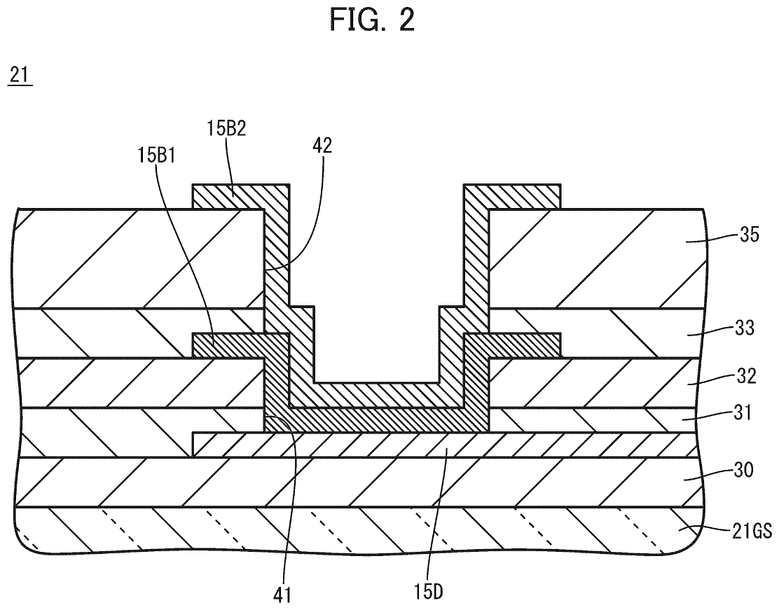

An organic EL panel (an example of a display panel) 11 according to a first embodiment will be described with reference to FIGS. 1 and 2. The organic EL panel 11 performs dot matrix display by an active matrix driving method using pixels arranged in a matrix in plan view. The organic EL panel 11 includes a plurality of organic electroluminescence (EL) elements arranged in a matrix on an array substrate 21.

FIG. 1 illustrates the cross-sectional configuration of a circuit 14 in a non-display region NAA of the array substrate 21. Regarding TFTs 15 and 27 described below in the array substrate 21 of this embodiment, the TFTs 15 and 27 in a display region AA have the same configurations as those in FIG. 1. In the display region AA, a pixel electrode and a common electrode connected to the second TFT 27 are disposed on the upper side of a fourth protective film 38 described below.

The array substrate 21 includes various types of films stacked and formed on the inner side of a glass substrate 21GS, which is almost transparent and has high light transmittance. The array substrate 21 includes a first TFT 15 as illustrated on the left side in FIG. 1. The first TFT 15 has a first gate electrode (an example of a first electrode) 15A, a first source relay electrode (an example of a first relay electrode) 15B1 and a first source electrode (an example of a second electrode) 15B2, a first drain relay electrode (an example of the first relay electrode) 15C1 and a first drain electrode (an example of the second electrode) 15C2, and a first semiconductor film 15D. The first semiconductor film 15D is located on the lowest layer side relative to the first gate electrode 15A, the first source relay electrode 15B1, the first source electrode 15B2, the first drain relay electrode 15C1, and the first drain electrode 15C2.

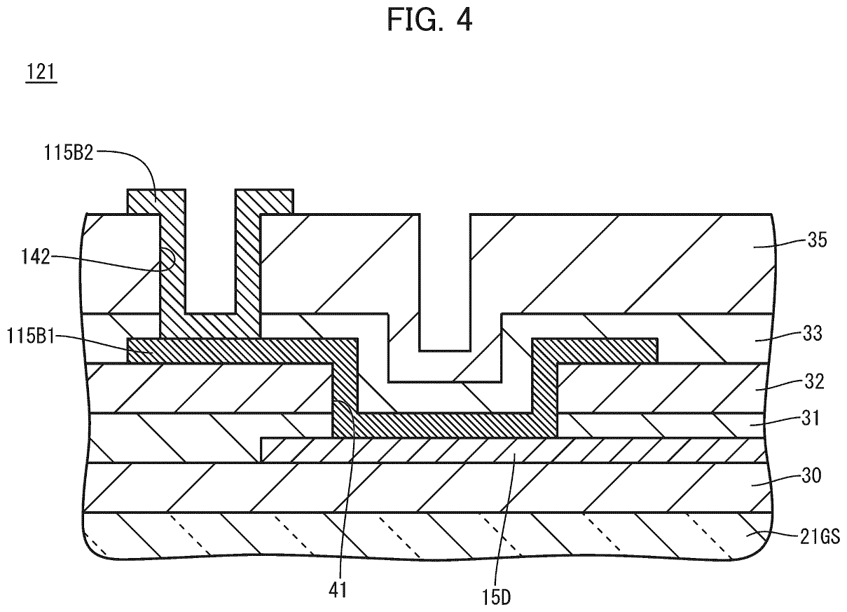

The array substrate 21 includes a storage capacitor (an example of a first storage capacitor) 16 as illustrated in the center of FIG. 4. The storage capacitor 16 has a first capacitor electrode 16A and a second capacitor electrode 16B. The first capacitor electrode 16A is located in a lower layer than the second capacitor electrode 16B.

The array substrate 21 includes the second TFT 27 as illustrated on the right side in FIG. 4. The second TFT 27 has a second gate electrode (an example of a third electrode) 27A, a second source electrode (an example of a fourth electrode) 27B, a second drain electrode (an example of the fourth electrode) 27C, and a second semiconductor film 27D.

The array substrate 21 includes the two types of TFTs 15 and 27 and the storage capacitor 16 and is formed by stacking and forming various types of films on the glass substrate 21GS (an example of an insulating substrate). The glass substrate 21GS contains, for example, alkali-free glass as a main material.

The array substrate 21 includes, in order from the lower layer side (glass substrate 21GS side),
a buffer layer (an example of a first insulating film) 30,
the first semiconductor film 15D,
a first gate insulating film (an example of a second insulating film) 31,
the first gate electrode (an example of the first electrode) 15A and the first capacitor electrode 16A each composed of a first metal film (an example of a first conducting film),
a first interlayer insulating film (an example of a third insulating film) 32,
the first source relay electrode (an example of the first relay electrode) 15B1, the first drain relay electrode (an example of the first relay electrode) 15C1, and the second capacitor electrode 16B each composed of a second metal film (an example of a second conducting film),
a first protective film (an example of a fourth insulating film or a fourth lower insulating film) 33,
the second semiconductor film 27D,
a second gate insulating film (an example of a fifth insulating film) 34,.
the second gate electrode (an example of the third electrode) 27A composed of a fourth metal film (an example of a fourth conducting film),
a second protective film (an example of the fourth insulating film or a fourth upper insulating film) 35,
the first source electrode (an example of the second electrode) 15B2, the first drain electrode (an example of the second electrode) 15C2, a connecting electrode (an example of a first connecting electrode) 16C, the second drain electrode (an example of the fourth electrode) 27C, and the second source electrode (an example of the fourth electrode) 27B each composed of a third metal film (an example of a third conducting film),
a third protective film 36,
a planarization film 37, and.
the fourth protective film 38, which are stacked and formed on one another.

The buffer layer 30, the first gate insulating film 31, the first interlayer insulating film 32, the first protective film 33, the second gate insulating film 34, the second protective film 35, the third protective film 36, and the fourth protective film 38 are made of inorganic materials (inorganic resin materials) and composed of, for example, a single-layer film or multilayer film containing SiO (oxidized silicon, silicon oxide) and/or SiN (silicon nitride). The second gate insulating film 34 has, for example, a thickness in the range of about 80 nm to 200 nm. The second gate insulating film 34 has a planar size that overlaps the second gate electrode 27A. The second gate insulating film 34 may be large enough to cover the second semiconductor film 27D or the entire first protective film 33. The buffer layer 30, the first gate insulating film 31, the first interlayer insulating film 32, the first protective film 33, and the second protective film 35 are thicker than the second gate insulating film 34 and are, for example, about 300 nm thick. A portion of the first gate insulating film 31 that is overlapped by the first gate electrode 15A has a thickness in the range of about 80 nm to 150 nm.

The planarization film 37 is made of an organic material (organic resin material), such as PMMA (acrylic resin). The planarization film is usually thicker than other insulating films made of inorganic materials. The planarization film 37 has a thickness of, for example, in the range of about 500 nm to 700 nm.

The first semiconductor film 15D is made of a crystalline polysilicon semiconductor material (LTPS) produced by a known method, such as laser crystallization. The polysilicon semiconductor material has higher electron mobility than oxide semiconductor materials.

The second semiconductor film 27D is made of an oxide semiconductor material. Oxide semiconductor materials have higher resistance under no applied voltage (off state) than polysilicon semiconductor materials. Oxide semiconductor materials have higher electron mobility than amorphous silicon semiconductor materials.

For example, an oxide semiconductor material containing at least one metal element selected from In, Ga, and Zn can be used as the oxide semiconductor material. The oxide semiconductor material may be amorphous or crystalline and is, for example, an In—Ga—Zn—O semiconductor (e.g., indium gallium zinc oxide). Examples of the oxide semiconductor material include In—Sn—Zn—O semiconductors (e.g., In2O3—SnO2—ZnO; InSnZnO), In—W—Zn—O semiconductors, In—W—Sn—Zn—O semiconductors, In—Al—Zn—O semiconductors, In—Al—Sn—Zn—O semiconductors, Zn—O semiconductors, In—Zn—O semiconductors, Zn—Ti—O semiconductors, Cd—Ge—O semiconductors, Cd—Pb—O semiconductors, CdO (cadmium oxide), Mg—Zn—O semiconductors, In—Ga—Sn—O semiconductors, In—Ga—O semiconductors, Zr—In—Zn—O semiconductors, Hf—In—Zn—O semiconductors, Al—Ga—Zn—O semiconductors, Ga—Zn—O semiconductors, and In—Ga—Zn—Sn—O semiconductors.

As described above, the first gate electrode 15A and the first capacitor electrode 16A are composed of the first metal film. The first gate electrode 15A is disposed above the first semiconductor film 15D with the first gate insulating film 31 therebetween so as to overlap the first semiconductor film 15D. The first gate electrode 15A overlaps a center portion of the first semiconductor film 15D. As illustrated in FIG. 1, the first capacitor electrode 16A is composed of a different portion of the first metal film from the first gate electrode 15A.

The first source relay electrode 15B1, the first drain relay electrode 15C1, and the second capacitor electrode 16B are composed of the second metal film. The first source relay electrode 15B1 overlaps one end portion of the first semiconductor film 15D, and the first drain relay electrode 15C1 overlaps the other end portion of the first semiconductor film 15D. The first source relay electrode 15B1 and the first drain relay electrode 15C1 are disposed near the first gate electrode 15A. The first source relay electrode 15B1 and the first drain relay electrode 15C1 are connected to the first semiconductor film 15D through two first contact holes 41 (and filled in the first contact holes 41) formed in the first gate insulating film 31 and the first interlayer insulating film 32. The first contact holes 41 are positioned such that the first source relay electrode 15B1 and the first drain relay electrode 15C1 each overlap the first semiconductor film 15D and do not overlap the first gate electrode 15A.

The second capacitor electrode 16B overlaps the first capacitor electrode 16A. As illustrated in FIG. 1, the first source relay electrode 15B1, the first drain relay electrode 15C1, and the second capacitor electrode 16B are each composed of a different portion of the second metal film.

The second gate electrode 27A is composed of the fourth metal film. The second gate electrode 27A is disposed above the second semiconductor film 27D with the second gate insulating film 34 therebetween. The second gate electrode 27A overlaps a center portion of the second semiconductor film 27D.

The first source electrode 15B2, the first drain electrode 15C2, the connecting electrode 16C, the second drain electrode 27C, and the second source electrode 27B are composed of the third metal film. The first source electrode 15B2 overlaps the first source relay electrode 15B1, and the first drain electrode 15C2 overlaps the first drain relay electrode 15C1. The first source electrode 15B2 and the first drain electrode 15C2 are respectively connected to the first source relay electrode 15B1 and the first drain relay electrode 15C1 through two second contact holes 42 (and filled in the second contact holes 42) formed in the first protective film 33 and the second protective film 35, and are therefore both connected to the first semiconductor film 15D. In this embodiment, the first contact holes 41 are coaxial with the second contact holes 42.

FIG. 2 is a partially enlarged view of an area where the first source electrode 15B2 is connected to the first source relay electrode 15B1 through the second contact hole 42 and the first source relay electrode 15B1 is connected to the first semiconductor film 15D through the first contact hole 41. As illustrated in the figure, the second metal film and the third metal film actually overlap each other in the first contact hole 41.

As illustrated in FIG. 1, the second source electrode 27B overlaps one end portion of the second semiconductor film 27D, and the second drain electrode 27C overlaps the other end portion of the second semiconductor film 27D. The second source electrode 27B and the second drain electrode 27C are disposed near the second gate electrode 27A. The second source electrode 27B and the second drain electrode 27C are connected to the second semiconductor film 27D through two third contact holes 43 (and filled in the third contact holes 43) formed in the second protective film 35. The third contact holes 43 are positioned such that the second source electrode 27B and the second drain electrode 27C each overlap the second semiconductor film 27D and do not overlap the second gate electrode 27A.

The connecting electrode 16C overlaps the second capacitor electrode 16B. The connecting electrode 16C is connected to the second capacitor electrode 16B through a fourth contact hole 44 (and filled in the fourth contact hole 44) formed in the second protective film 35 and the first protective film 33. The connecting electrode 16C extends from the second drain electrode 27C to the upper side of the second capacitor electrode 16B such that the connecting electrode 16C is extended to the second drain electrode 27C. In other words, the connecting electrode 16C is integrated with the second drain electrode 27C.

As illustrated in FIG. 1, the first source electrode 15B2, the first drain electrode 15C2, the integrated connecting electrode 16C and second drain electrode 27C, and the second source electrode 27B are each composed of a different portion of the third metal film.

The third metal film and the fourth metal film are single-layer films made of only copper (Cu), or multilayer films or alloys made of copper (Cu) and one or more different types of metal materials selected from molybdenum (Mo), titanium (Ti), aluminum (Al), chromium (Cr), gold (Au), nickel (Ni), and neodymium (Nd). The third metal film and the fourth metal film have electrical conductivity and light-shielding properties. The first metal film and the second metal film are single-layer films made of any one of the above-mentioned metals other than copper (Cu), or multilayer films or alloys made of different types of metal materials other than copper (Cu).

Next, the method for producing the array substrate 21 of this embodiment will be described. For the array substrate 21, the first semiconductor film 15D is formed on the buffer layer 30 on the glass substrate 21GS by patterning, and the first gate insulating film 31 is deposited on the upper side of the first semiconductor film 15D. Next, the first metal film is deposited on the upper side of the first gate insulating film 31 and patterned to form the first gate electrode 15A overlapping a portion of the first semiconductor film 15D and the first capacitor electrode 16A not overlapping the first semiconductor film 15D, and the first interlayer insulating film 32 is deposited on the upper side of the first metal film.

The term “patterning” refers to film processing based on general photolithography. Specifically, the term “patterning” means depositing a photoresist film on a target film, exposing the photoresist film by using an exposure device through a photomask having a predetermined pattern, then developing the photoresist film, and etching the target film through the developed photoresist film.

Next, the first interlayer insulating film 32 and the first gate insulating film 31 are patterned by etching to form two first contact holes 41 overlapping portions of the first semiconductor film 15D but not overlapping the first gate electrode 15A. The first semiconductor film 15D functions as an etching stop film.

Next, the second metal film is deposited on the upper side of the first interlayer insulating film 32, and the second metal film is patterned to form the first source relay electrode 15B1 and the first drain relay electrode 15Cl overlapping the first contact holes 41 and connected to the first semiconductor film 15D through the first contact holes 41, and the second capacitor electrode 16B overlapping the first capacitor electrode 16A.

Next, the first protective film 33 is formed on the second metal film, and the second semiconductor film 27D is formed on the first protective film 33 by patterning. After the second gate insulating film 34 is deposited on the upper side of the second semiconductor film 27D, the fourth metal film is deposited on the upper side of the second gate insulating film 34 and patterned to form the second gate electrode 27A overlapping a portion of the second semiconductor film 27D. The second protective film 35 is then deposited on the upper side of the second gate electrode 27A.

Next, the second protective film 35 and the first protective film 33 are patterned by etching to form two second contact holes 42 overlapping the first source relay electrode 15B1 and the first drain relay electrode 15C1, the fourth contact hole 44 overlapping the second capacitor electrode 16B, and two third contact holes 43 overlapping portions of the second semiconductor film 27D but not overlapping the second gate electrode 27A. The first source relay electrode 15B1, the first drain relay electrode 15C1, the second capacitor electrode 16B, and the second semiconductor film 27D function as etching stop films. In this case, the second contact holes 42 are coaxial with the first contact holes 41.

Next, the third metal film is deposited on the upper side of the second protective film 35, and the third metal film is patterned to form the first source electrode 15B2 and the first drain electrode 15C2 overlapping the second contact holes 42 and respectively connected to the first source relay electrode 15B1 and the first drain relay electrode 15C1 through the first contact holes 41, the connecting electrode 16C overlapping the fourth contact hole 44 and connected to the second capacitor electrode 16B, and the second drain electrode 27C and the second source electrode 27B connected to the second semiconductor film 27D through the third contact holes 43. In this case, the connecting electrode 16C and the second drain electrode 27C are integrally formed.

Subsequently, the third protective film 36, the planarization film 37, and the fourth protective film 38 are formed in order on the upper side of the third metal film (the first source electrode 15B2, the first drain electrode 15C2, the connecting electrode 16C, the second drain electrode 27C, and the second source electrode 27B).

Next, the operation and effect will be described. The array substrate 21 of this embodiment includes the first TFT 15 including: the buffer layer 30 disposed on the upper side of the glass substrate 21GS; the first semiconductor film 15D disposed on the buffer layer 30 and made of a low-temperature polysilicon semiconductor material (LTPS); the first gate insulating film 31 disposed on the first semiconductor film 15D; the first gate electrode 15A disposed on the first gate insulating film 31 and composed of the first metal film overlapping the first semiconductor film 15D; the first interlayer insulating film 32 disposed on the first gate electrode 15A; the first source relay electrode 15B1 and the first drain relay electrode 15Cl composed of different parts and each composed of the second metal film free of copper and disposed on the first interlayer insulating film 32, the first source relay electrode 15B1 and the first drain relay electrode 15C1 being connected to the first semiconductor film 15D through the first contact holes 41 penetrating the first interlayer insulating film 32 and the first gate insulating film 31; the first protective film 33 and the second protective film 35 disposed on the first source relay electrode 15B1 and the first drain relay electrode 15C1; the first source electrode 15B2 and the first drain electrode 15C2 each composed of the third metal film containing copper and disposed on the first protective film 33 and the second protective film 35, the first source electrode 15B2 and the first drain electrode 15C2 being respectively connected to the first source relay electrode 15B1 and the first drain relay electrode 15C1 through the two second contact holes 42 penetrating the first protective film 33 and the second protective film 35.

According to the above configuration, the second metal film (the first source relay electrode 15B1 and the first drain relay electrode 15C1) directly connected to the first semiconductor film 15D made of a low-temperature polysilicon semiconductor material (LTPS) is free of copper (Cu), so that copper (Cu) in the wires of the entire array substrate 21 is unlikely to penetrate the first semiconductor film 15D made of LTPS. On the other hand, the third metal film (the first source electrode 15B2 and the first drain electrode 15C2) away from the first semiconductor film 15D contains copper and has low resistance.

The array substrate 21 includes the storage capacitor 16 having: the first capacitor electrode 16A disposed on the first gate insulating film 31 and composed of the first metal film different from that of the first gate electrode 15A; and the second capacitor electrode 16B disposed on the first interlayer insulating film 32, composed of the second metal film different from those of the first source relay electrode 15B1 and the first drain relay electrode 15C1, and overlapping the first capacitor electrode 16A.

The array substrate 21 of this embodiment includes the second TFT 27 including: the second semiconductor film 27D disposed on the first protective film 33 and made of an oxide semiconductor material; the second gate insulating film 34 disposed on the second semiconductor film 27D and overlapping the second semiconductor film 27D; the second gate electrode 27A disposed on the second gate insulating film 34 and composed of the fourth metal film overlapping the second semiconductor film 27D; the second protective film 35 disposed on the second gate electrode 27A; and the second source electrode 27B and the second drain electrode 27C disposed on the second protective film 35 and connected to the second semiconductor film 27D through the third contact holes 43 penetrating the second protective film 35, the second source electrode 27B and the second drain electrode 27C being composed of the third metal film different from those of the first source electrode 15B2 and the first drain electrode 15C2. The array substrate 21 also includes the connecting electrode 16C disposed on the second protective film 35 and connected to the second capacitor electrode 16B through the fourth contact hole 44 penetrating the second protective film 35 and the first protective film 33, the connecting electrode 16C being connected to the second drain electrode 27C and composed of the third metal film.

The third metal film containing copper is thus connected to the second TFT formed by using an oxide semiconductor material that is less susceptible to copper (Cu).

### Second Embodiment

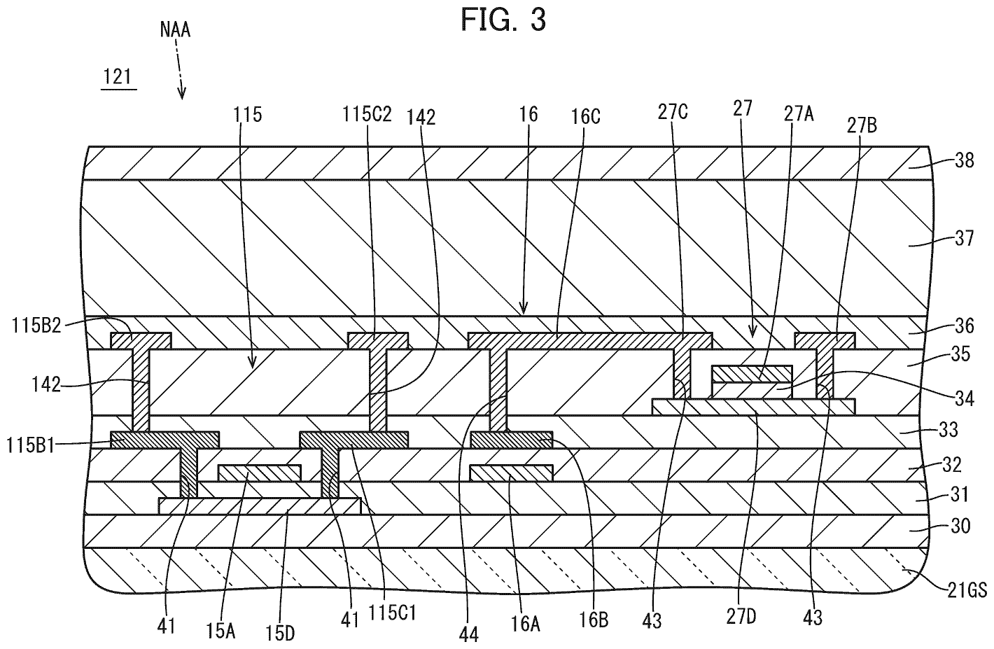

A first TFT 115 of an array substrate 121 according to a second embodiment will be described with reference to FIGS. 3 and 4. Only the components that differ from those in the first embodiment will be described below. The same components as those in the first embodiment will be assigned the same reference signs, and redundant description will be omitted.

The first TFT 115 differs from the first embodiment in that the axes of second contact holes 142 are located at different positions from the axes of the first contact holes 41 in the plane direction of the array substrate 121, and the second contact holes 142 are not coaxial with the first contact holes 41. A first source relay electrode 115B1 and a first drain relay electrode 115C1 are separated from each other more outward (in the direction away from the first gate electrode 15A) than in the first embodiment, and the two second contact holes 142 are farther apart from each other than the two first contact holes 41.

In the case where the first contact holes are coaxial with the second contact holes (in the case of the first embodiment 1) and if defects occur in the coverage of the second metal film (the first source relay electrode 15B1 and the first drain relay electrode 15C1) on the first semiconductor film 15D in the first contact holes 41 as illustrated in FIG. 2, there is a concern that copper (Cu) in the third metal film (the first source electrode 15B2 and the first drain electrode 15C2) overlapping the second metal film in the first contact holes 41 penetrates and diffuses into the first semiconductor film 15D from the defects in the second metal film described above. According to the first TFT 115 of this embodiment, as illustrated in FIG. 4, the third metal film (a first source electrode 115B2 and a first drain electrode 115C2) is disposed on portions of the second metal film (the first source relay electrode 115B1 and the first drain relay electrode 115C1) that are positioned away from the first semiconductor film 15D. The third metal film does not overlap portions (in the first contact holes 41) of the second metal film that overlaps the first semiconductor film 15D, thereby reducing the possibility of copper (Cu) diffusion.

In other words, according to the array substrate 121 of this embodiment, the first semiconductor film 15D and the copper (Cu)-containing wires (the third metal film) are farther apart from each other than those in the structure of the first embodiment in which the first contact holes 41 are coaxial with the second contact holes 42, so that it is more difficult for copper (Cu) to penetrate the first semiconductor film 15D.

### Third Embodiment

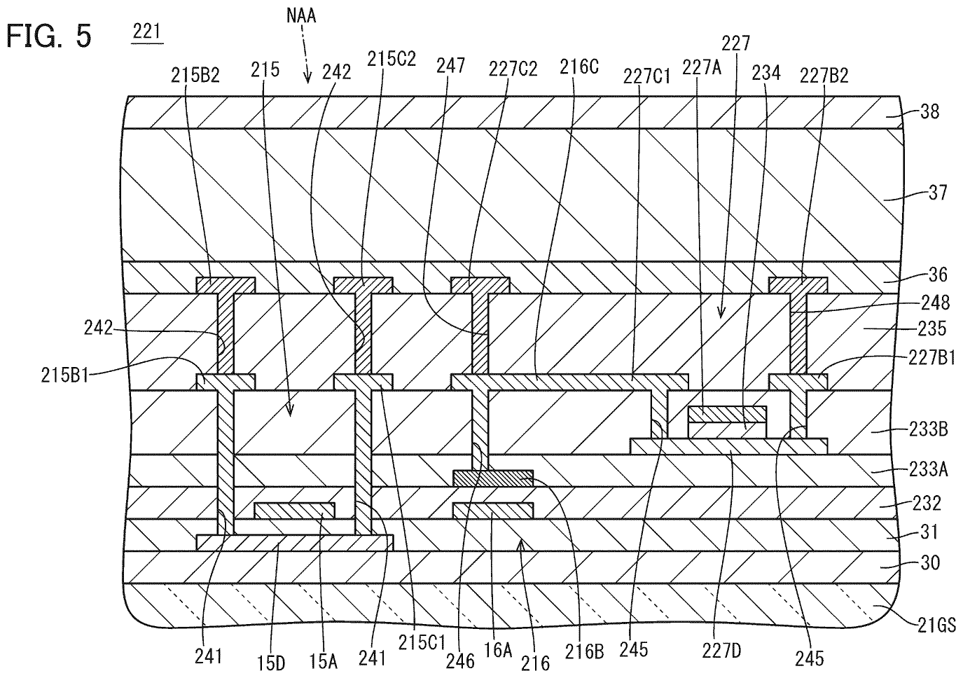

An array substrate 221 according to a third embodiment will be described with reference to FIG. 5. Only the components that differ from those in the first embodiment will also be described below. The same components as those in the first embodiment will be assigned the same reference signs, and redundant description will be omitted.

The array substrate 221 of this embodiment differs from the above embodiments in that the copper (Cu)-containing wires (a first source electrode 215B2 and a first drain electrode 215C2) are farther apart from the first semiconductor film 15D in the plate thickness direction (Z-direction). The array substrate 221 has three insulating films (examples of third insulating films) 232, 233A, and 233B between the first gate electrode 15A and a first source relay electrode 215B1 and between the first gate electrode 15A and a first drain relay electrode 215C1.

Specifically, the array substrate 221 includes, in order from the lower layer side (glass substrate 21GS side),
the buffer layer (an example of the first insulating film) 30,
the first semiconductor film 15D,
the first gate insulating film (an example of the second insulating film) 31,
the first gate electrode 15A and the first capacitor electrode 16A each composed of the first metal film (an example of the first conducting film),
a second interlayer insulating film (an example of a third lower insulating film) 232,
a third capacitor electrode 216B composed of a fifth metal film (an example of a fifth conducting film),
a fifth protective film (an example of a third middle insulating film) 233A,
a third semiconductor film 227D,
a third gate insulating film (an example of a sixth insulating film) 234,
a third gate electrode (an example of a fifth electrode) 227A composed of a sixth metal film (sixth conducting film),
a sixth protective film (an example of a third upper insulating film) 233B,
the first source relay electrode 215B1, the first drain relay electrode 215C1, a connecting electrode (an example of a second connecting electrode) 216C, a third drain relay electrode (an example of a second relay electrode) 227C1, and a third source relay electrode (an example of the second relay electrode) 227B1 each composed of the second metal film (second conducting film),
a seventh protective film (an example of the fourth insulating film) 235,.
the first source electrode 215B2, the first drain electrode 215C2, a third drain electrode (an example of a sixth electrode) 227C2, and a third source electrode (an example of the sixth electrode) 227B2 each composed of the third metal film (an example of the third conducting film),
the third protective film 36,
the planarization film 37, and
the fourth protective film 38, which are stacked and formed on one another.

The first source relay electrode 215B1 and the first drain relay electrode 215C1 are connected to the first semiconductor film 15D through two first contact holes 241 (and filled in the first contact holes 241) formed in the sixth protective film 233B, the fifth protective film 233A, the second interlayer insulating film 232, and the first gate insulating film 31. The first source electrode 215B2 and the first drain electrode 215C2 are respectively connected to the first source relay electrode 215B1 and the first drain relay electrode 215C1 through two second contact holes 242 (and filled in the second contact holes 242) formed in the seventh protective film (an example of the fourth insulating film) 235, and are therefore both connected to the first semiconductor film 15D. In this embodiment, the first contact holes 241 are coaxial with the second contact holes 242.

The third drain relay electrode 227C1 and the third source relay electrode 227B1 are connected to the third semiconductor film 227D through two fifth contact holes 245 (and filled in the fifth contact holes 245) formed in the sixth protective film 233B.

The connecting electrode 216C is connected to the third capacitor electrode 216B through a sixth contact hole 246 (and filled in the sixth contact hole 246) formed in the sixth protective film 233B and the fifth protective film 233A. The connecting electrode 216C extends from the third drain relay electrode 227C1 to the upper side of the third capacitor electrode 216B such that the connecting electrode 216C is extended to the third drain relay electrode 227C1. In other words, the connecting electrode 216C is integrated with the third drain relay electrode 227C1.

The third drain electrode 227C2 is connected to the connecting electrode 216C and the third drain relay electrode 227C1 through a seventh contact hole 247 (and filled in the seventh contact hole 247) formed in the seventh protective film 235. The third source electrode 227B2 is connected to the third source relay electrode 227B1 through an eighth contact hole 248 (and filled in the eighth contact hole 248) formed in the seventh protective film 235. The third drain electrode 227C2 and the third source electrode 227B2 are therefore both connected to the third semiconductor film 227D.

Next, the operation and effect will be described. The array substrate 221 of this embodiment includes a first TFT 215 including: the buffer layer 30 disposed on the upper side of the glass substrate 21GS; the first semiconductor film 15D disposed on the buffer layer 30 and made of a low-temperature polysilicon semiconductor material (LTPS); the first gate insulating film 31 disposed on the first semiconductor film 15D; the first gate electrode 15A disposed on the first gate insulating film 31 and composed of the first metal film overlapping the first semiconductor film 15D; the first source relay electrode 215B1 and the first drain relay electrode 215C1 composed of different parts and each made of the second metal free of copper and disposed on the insulating films including the second interlayer insulating film 232, the fifth protective film 233A, and the sixth protective film 233B on the first gate electrode 15A, the first source relay electrode 215B1 and the first drain relay electrode 215C1 being connected to the first semiconductor film 15D through the first contact holes 241 penetrating the sixth protective film 233B, the fifth protective film 233A, the second interlayer insulating film 232, and the first gate insulating film 31; the seventh protective film 235 disposed on the first source relay electrode 215B1 and the first drain relay electrode 215C1; and the first source electrode 215B2 and the first drain electrode 215C2 each made of the third metal containing copper and disposed on the seventh protective film 235, the first source electrode 215B2 and the first drain electrode 215C2 being respectively connected to the first source relay electrode 215B1 and the first drain relay electrode 215C1 through the second contact holes 242 penetrating the seventh protective film 235.

According to this configuration, the first source electrode 215B2 and the first drain electrode 215C2 are located farther away from the first semiconductor film 15D than those in the first embodiment, and it is thus more difficult for copper (Cu) in the wires of the array substrate 221 to penetrate the first semiconductor film 15D made of LTPS.

The array substrate 221 of this embodiment also has a storage capacitor (an example of a second storage capacitor) 216 having the first capacitor electrode 16A composed of the first metal film disposed on the first gate insulating film 31 and the third capacitor electrode 216B composed of the fifth metal film disposed on the second interlayer insulating film 232.

The array substrate 221 of this embodiment includes a third TFT 227 including: the third semiconductor film 227D disposed on the fifth protective film 233A and made of an oxide semiconductor material; the third gate insulating film 234 disposed on the third semiconductor film 227D and overlapping the third semiconductor film 227D; the third gate electrode 227A disposed on the third gate insulating film 234 and made of the sixth metal overlapping the third semiconductor film 227D; the sixth protective film 233B disposed on the third gate electrode 227A; and the third drain relay electrode 227C1 and the third source relay electrode 227B1 disposed on the sixth protective film 233B and connected to the third semiconductor film 227D through the fifth contact holes 245 penetrating the sixth protective film 233B, the third drain relay electrode 227C1 and the third source relay electrode 227B1 being composed of the second metal film different from those of the first source relay electrode 215B1 and the first drain relay electrode 215C1. The array substrate 221 includes the third TFT 227 including: a connecting electrode 216C disposed on the sixth protective film 233B and connected to the third capacitor electrode 216B through the sixth contact hole 246 penetrating the sixth protective film 233B and the fifth protective film 233A, the connecting electrode 216C being connected to the third drain relay electrode 227C1 and composed of the second metal film different from those of the first source relay electrode 215B1 and the first drain relay electrode 215C1; the third drain electrode 227C2 disposed on the seventh protective film 235 and composed of the third metal film different from those of the first source electrode 215B2 and the first drain electrode 215C2, the third drain electrode 227C2 being connected to the connecting electrode 216C through the seventh contact hole 247 penetrating the seventh protective film 235; and a third source electrode 227B2 connected to the third source relay electrode 227B1, which is not connected to the connecting electrode 216C, through the eighth contact hole 248 penetrating the seventh protective film 235.

### Fourth Embodiment

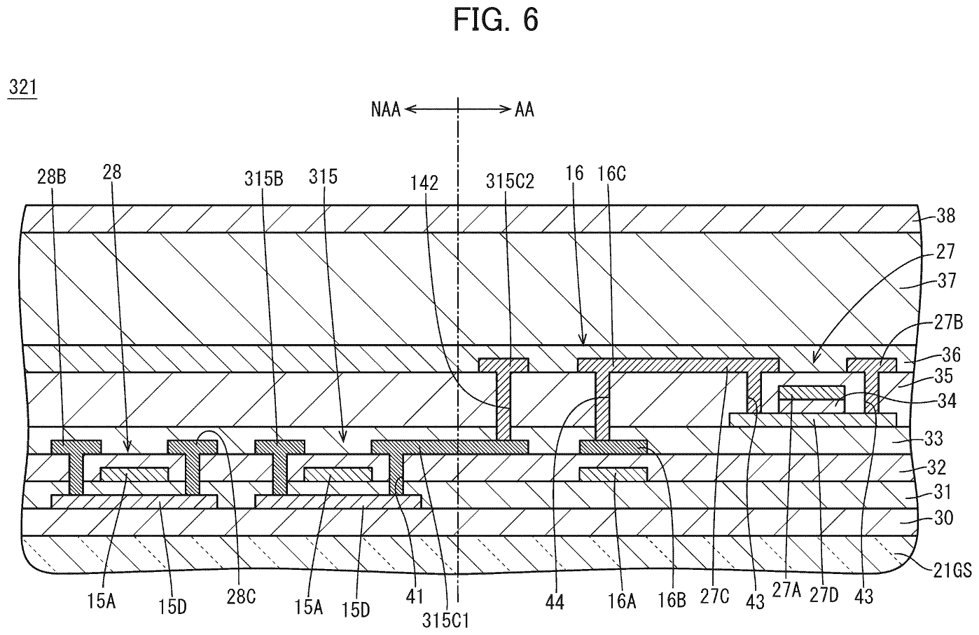

An array substrate 321 according to a fourth embodiment will be described with reference to FIG. 6. Only the components that differ from those in the second embodiment will be described below. The same components as those in the second embodiment will be assigned the same reference signs, and redundant description will be omitted.

The array substrate 321 of this embodiment differs from the second embodiment in that a first TFT 315 has a drain electrode (an example of the second electrode) 315C2 composed of the third metal film but no source electrode composed of the third metal film. In the gate driver circuit in the non-display region NAA, for example, multiple TFTs per raw of gate signal lines form a single circuit, and a source electrode or drain electrode composed of the third metal film containing copper is not connected to all of these TFTs. Among these TFTs, the first TFT 315, which is finally connected to a gate signal line in the display region AA, is provided with only the drain electrode 315C2 composed of the third metal film containing copper. In other words, the first TFT 315 of this embodiment is provided with no source electrode composed of the third metal film containing copper, and an electrode composed of the second metal film free of copper forms a source electrode 315B. In FIG. 6, a TFT with no relay electrode in the non-display region NAA is referred to as a fourth TFT 28, and a source electrode and a drain electrode each composed of the second metal film free of copper in the fourth TFT 28 are assigned reference signs 28B and 28C, respectively.

### Other Embodiments

This technology is not limited to the embodiments in the above description and drawings, and for example, the following embodiments are also included in the technical scope.

(1) The above embodiments describe the array substrates and display panels having the first TFT 15, 115, 215, or 315 having the first semiconductor film 15D made of a low-temperature polysilicon semiconductor material (LTPS), and the second TFT 27 or the third TFT 227 made of an oxide semiconductor material. Any array substrate and display panel including only the first TFT are also included in the technical scope.

(2) The above embodiments illustrate forms in which the first gate insulating film 31 covering the entire first semiconductor film 15D is formed on the first semiconductor film 15D, but the first gate insulating film may be an insulating film having the same size as the first gate electrode 15A.

(3) The second embodiment illustrates a form in which the two second contact holes 142 are farther apart from each other than the two first contact holes 41, but the two second contact holes may be closer to each other than the two first contact holes. In other words, this embodiment includes a form in which the first contact holes are not coaxial with the second contact holes.

(4) The first embodiment illustrates a top-gate type in which the second semiconductor film 27D is located below the second gate electrode 27A, the second source electrode 27B, and the second drain electrode 27C. In the application of liquid crystal displays, a bottom-gate type may be employed.

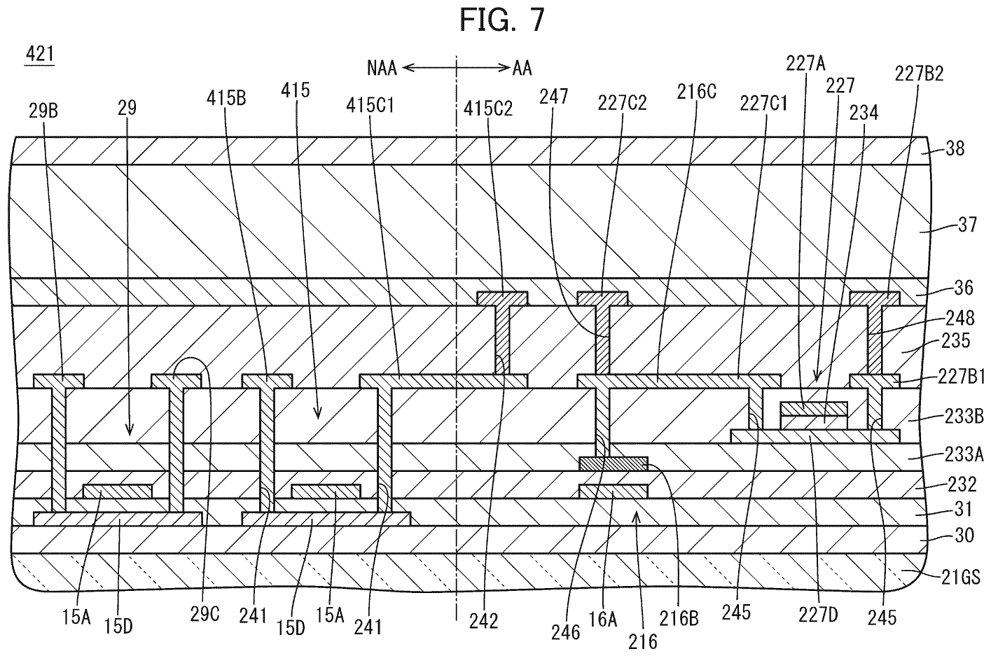

(5) In the array substrate 321 of the fourth embodiment including some of the components of the second embodiment, the first TFT 315 has the drain electrode (an example of the second electrode) 315C2 composed of the third metal film but no source electrode composed of the third metal film. In an array substrate 421 including some of the components of the third embodiment, as illustrated in FIG. 7, a first TFT 415 may have a drain electrode (an example of the second electrode) 415C2 composed of the third metal film but no source electrode composed of the third metal film as in the fourth embodiment. In this case, a fourth TFT 29 including no relay electrode in the non-display region NAA includes a source electrode 29B and a drain electrode 29C each composed of the second metal film free of copper.

(6) This technology can be applied not only to organic EL panels but also to other types of display panels, such as liquid crystal panels.

The present disclosure contains subject matter related to that disclosed in Japanese Priority Patent Application JP 2024-097338 filed in the Japan Patent Office on Jun. 17, 2024, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An array substrate comprising a first TFT including:
a first insulating film disposed on an upper side of an insulating substrate;
a first semiconductor film disposed on the first insulating film and made of a low-temperature polysilicon semiconductor material;
a second insulating film disposed on the first semiconductor film;
a first electrode disposed on the second insulating film and composed of a first conducting film overlapping the first semiconductor film;
a third insulating film disposed on the first electrode;
a first relay electrode composed of a second conducting film free of copper and disposed on the third insulating film, the first relay electrode being connected to the first semiconductor film through a first contact hole penetrating at least the third insulating film;
a fourth insulating film disposed on the first relay electrode; and
a second electrode composed of a third conducting film containing copper and disposed on the fourth insulating film, the second electrode being connected to the first relay electrode through a second contact hole penetrating the fourth insulating film.

2. The array substrate according to claim 1, wherein the first contact hole is located at a different position from the second contact hole in a plane direction of the array substrate.

3. The array substrate according to claim 1, comprising a first storage capacitor including:
a first capacitor electrode disposed on the second insulating film and composed of the first conducting film different from the first conducting film of the first electrode; and
a second capacitor electrode disposed on the third insulating film and composed of the second conducting film different from the second conducting film of the first relay electrode, the second capacitor electrode overlapping the first capacitor electrode.

4. The array substrate according to claim 3, wherein
the fourth insulating film includes a fourth lower insulating film and a fourth upper insulating film disposed on the fourth lower insulating film, and
the array substrate comprises a second TFT including:
a second semiconductor film disposed on the fourth lower insulating film and made of an oxide semiconductor material;
a fifth insulating film disposed on the second semiconductor film and overlapping the second semiconductor film;
a third electrode disposed on the fifth insulating film and composed of a fourth conducting film overlapping the second semiconductor film;
the fourth upper insulating film disposed on the third electrode; and
a fourth electrode disposed on the fourth upper insulating film and connected to the second semiconductor film through a third contact hole penetrating at least the fourth upper insulating film, the fourth electrode being composed of the third conducting film different from the third conducting film of the second electrode.

5. The array substrate according to claim 4, comprising a first connecting electrode disposed on the fourth insulating film and connected to the second capacitor electrode through a fourth contact hole penetrating the fourth insulating film, the first connecting electrode being connected to the fourth electrode and composed of the third conducting film.

6. The array substrate according to claim 1, wherein
the third insulating film includes a third lower insulating film, a third middle insulating film disposed on the third lower insulating film, and a third upper insulating film disposed on the third middle insulating film, and
the array substrate comprises a second storage capacitor including:
a first capacitor electrode disposed on the second insulating film and composed of the first conducting film different from the first conducting film of the first electrode; and
a third capacitor electrode disposed on the third lower insulating film and composed of a fifth conducting film overlapping the first capacitor electrode.

7. The array substrate according to claim 6, comprising:
a third semiconductor film disposed on the third middle insulating film and made of an oxide semiconductor material;
a sixth insulating film disposed on the third semiconductor film and overlapping the third semiconductor film;
a fifth electrode disposed on the sixth insulating film and composed of a sixth conducting film overlapping the third semiconductor film;
the third upper insulating film disposed on the fifth electrode; and
a second relay electrode disposed on the third upper insulating film and connected to the third semiconductor film through a fifth contact hole penetrating at least the third upper insulating film, the second relay electrode being composed of the second conducting film different from the second conducting film of the first relay electrode.

8. The array substrate according to claim 7, comprising:
a second connecting electrode disposed on the third upper insulating film and connected to the third capacitor electrode through a sixth contact hole penetrating at least the third upper insulating film and the third middle insulating film, the second connecting electrode being connected to the second relay electrode and composed of the second conducting film different from the second conducting film of the first relay electrode; and
a sixth electrode disposed on the fourth insulating film and composed of the third conducting film different from the third conducting film of the second electrode, the sixth electrode being connected to the second connecting electrode through a seventh contact hole penetrating the fourth insulating film.

9. The array substrate according to claim 8, comprising the sixth electrode connected to the second relay electrode, which is not connected to the second connecting electrode, through an eighth contact hole penetrating the fourth insulating film.

10. A display panel comprising the array substrate according to claim 1.
